(19) United States
(12) Patent Application Publication
(10) Pub. No.: US 2008/0230872 A1
(43) Pub. Date: Sep. 25, 2008

(54) BIPOLAR TRANSISTOR AND METHOD FOR MANUFACTURING THE SAME

(76) Inventor: Nam-Joo Kim, Yongin-si (KR)

Correspondence Address: SHERR & NOURSE, PLLC, 620 HERNDON PARKWAY, SUITE 200, HERNDON, VA, 20170, US

(21) Appl. No.: 12/049,672

(22) Filed: Mar. 17, 2008

(30) Foreign Application Priority Data
Mar. 19, 2007 (KR) 10-2007-0026729

(51) Int. Cl. H01L 29/73; H01L 21/331

(52) U.S. Cl. 257/588; 438/342; 257/E29.174; 257/E21.37

(57) ABSTRACT

A bipolar transistor and a method for manufacturing the same. The bipolar transistor can include a collector region formed in a substrate, an epitaxial layer formed over the substrate including the collector region, a base region formed in the epitaxial layer, an emitter region formed in the base region, an oxide layer formed on sidewalls of a trench extending through the emitter region, the base region, the epitaxial layer and in the collector region, and a polysilicon layer formed in the trench.

The present application claims priority under 35 U.S.C. 119 and 35 U.S.C. 365 to Korean Patent Application No. 10-2007-0026729 (filed on Mar. 19, 2007), which is hereby incorporated by reference in its entirety.

### BACKGROUND

A bipolar junction transistor may exhibit a higher current driving performance and a faster operation speed when compared with those of a MOS field effect transistor. In order to obtain high-speed data processing, such a bipolar junction transistor may include a complementary bipolar transistor, in which a PNT bipolar junction transistor and an NPN bipolar junction transistor are integrated on a silicon substrate.

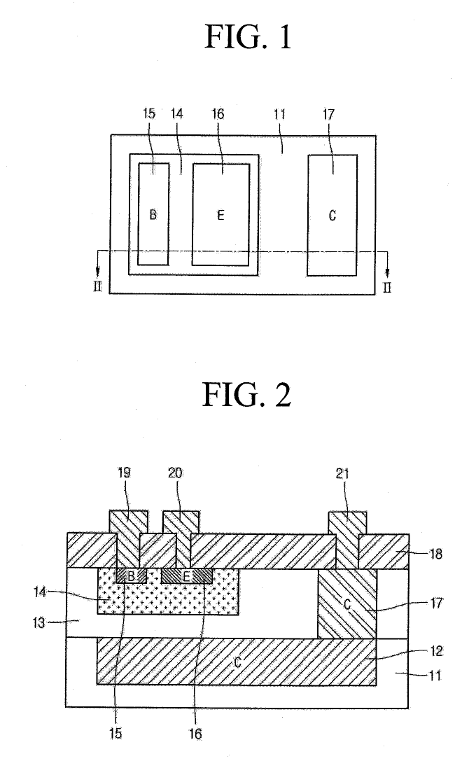

As illustrated in example FIGS. 1 and 2, an NPN bipolar transistor may include N+ type buried layer 12 formed in silicon substrate 11. Epitaxial layer 13 may be formed on and/or over the entire surface of silicon substrate 11 including N+ type buried layer 12 and N− type well 14 may be formed in the surface of epitaxial layer 13. Base region 15 and emitter region 16 may be formed spaced apart a predetermined distance in the surface of epitaxial layer 13 including N− type well 14. N+ type diffusion region 17 may be formed in epitaxial layer 13 and in connection with N+ type buried layer 12. Interlayer dielectric layer 18 may be formed on and/or over the entire surface of silicon substrate 11 including epitaxial layer 13. Base electrode 19, emitter electrode 20 and collector electrode 21 may extend through interlayer dielectric layer 18 for connection to base region 15, emitter region 16, and N+ type diffusion region 17, respectively. N+ type buried layer 12 may be used as a collector region.

Such a NPN bipolar transistor, however, may exhibit problems. Particularly, when forming the collector, N+ type buried layer 12 and the surface of silicon substrate 11 are connected to high-density N+ type diffusion region 17 referred to as a sink. This sink is subject to several heat treatments and N-type high density ion implantation in order to connect with N+ type buried layer 12 under epitaxial layer 13 from the upper portion of silicon substrate 11. In such a case, the junction may extend laterally thereof corresponding to a depth of a lower portion thereof. Moreover, the sink may cause internal pressure with a base junction, and thus, a predetermined distance must be maintained between N+ type diffusion region 17 and N− type well 14. Therefore, when the sink is used as the junction, the size of the transistor is increased due to such problems.

### SUMMARY

Embodiments relate to a bipolar transistor and a method for manufacturing the same, that can enhance an isolation structure between semiconductor layers, thereby reducing the size of a collector. Such a structure can also permit current to flow through the shortest path between the semiconductor layers, and minimize the resistance of the collector.

Embodiments relate to a bipolar transistor that can include at least one of the following: a collector region formed in a substrate; an epitaxial layer formed over the substrate including the collector region; a base region formed in the epitaxial layer; an emitter region formed in the base region; an oxide layer formed on sidewalls of a trench extending through the emitter region, the base region, the epitaxial layer and in the collector region; and a polysilicon layer formed in the trench.

Embodiments relate to a method for manufacturing a bipolar transistor that can include at least one of the following steps: forming a collector region in a substrate; forming an epitaxial layer over the substrate including the collector region; forming a base region in the epitaxial region; forming an emitter region in the base region; forming a trench through the emitter region, the base region, the epitaxial layer and in the collector region; forming an oxide layer on sidewalls of the trench; and then forming a polysilicon layer in the trench.

Embodiments relate to a bipolar transistor that can include at least one of the following: a first region composed of N+ type impurity ions formed in a substrate; an epitaxial layer formed over the substrate including the first region; a second region composed of P+ type impurity ions formed in the epitaxial layer; a third region composed of N+ type impurity ions formed in the second region; an oxide layer formed on sidewalls of a trench extending through the third region, the second region, the epitaxial layer and in the first region; a polysilicon layer formed in the trench extending through the third region, the second region and the epitaxial layer and into the first region; a fourth region composed of N type impurity ions formed in the first region under the oxide layer and the polysilicon layer; and a plurality of electrodes formed in electrical communication with the second region, the third region, and the polysilicon layer, respectively.

### DRAWINGS

Example FIGS. 1 and 2 illustrate a bipolar transistor.

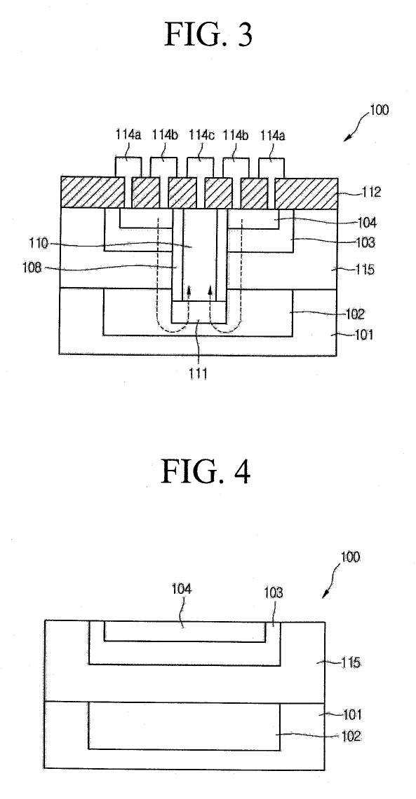

Example FIGS. 3 to 12 illustrates a bipolar transistor, in accordance with embodiments.

### DESCRIPTION

In accordance with embodiments, example FIG. 3 illustrates bipolar transistor 100 that can be formed as an NPN-type transistor. Bipolar transistor 100 can include collector region 102 formed in substrate 101. Epitaxial layer 115 can be formed on and/or over substrate 101 including collector region 102. Base region 103 can be formed in epitaxial layer 115 while emitter region 104 can be formed in base region 103. Oxide layer 108 can be formed on both sidewalls of a trench extending through emitter region 104, base region 103, and epitaxial region 115 to an inner portion of collector region 102. Polysilicon layer 110 can be formed in the trench to contact oxide layer 108. Diffusion region 111 can be formed at a lower portion of collector region 102 to contact polysilicon layer 110 and oxide layer 108. Interlayer dielectric layer 112 can be formed on and/or over the entire surface of the epitaxial layer 115 and having contact holes exposing a portion of base region 103, emitter region 104 and polysilicon region 110. Through the contact holes, base electrode 114a, emitter electrode 114b and collector electrode 114c can be in electric communication with base region 103, emitter region 104 and polysilicon layer 110, respectively.

Example FIGS. 4 to 12 illustrate a method of manufacturing bipolar transistor 100, in accordance with embodiments.

As illustrated in example FIG. 4, N type impurity ions can be selectively implanted into substrate 101, thereby forming an N+ buried layer (NBL), i.e., collector region 102 having a predetermined width in substrate 101. Substrate 101 can be composed of silicon. Epitaxial layer 115 can then be formed on and/or over substrate 101 by growing substrate 101 including collector region 102 through an epitaxial process. Once epitaxial layer 115 has been formed, P type impurity ions can be selectively implanted to thereby form P+ type base region 103 and N type impurity ions can be selectively implanted into base region 103 to thereby form the N+ type emitter region 104.

A trench can then be formed extending through emitter region 104, base region 103, and epitaxial region 115 to the inside of collector region 102. Oxide layer 108 can then be formed on both sidewalls of the trench. The trench and oxide layer 108 may be formed through various processes.

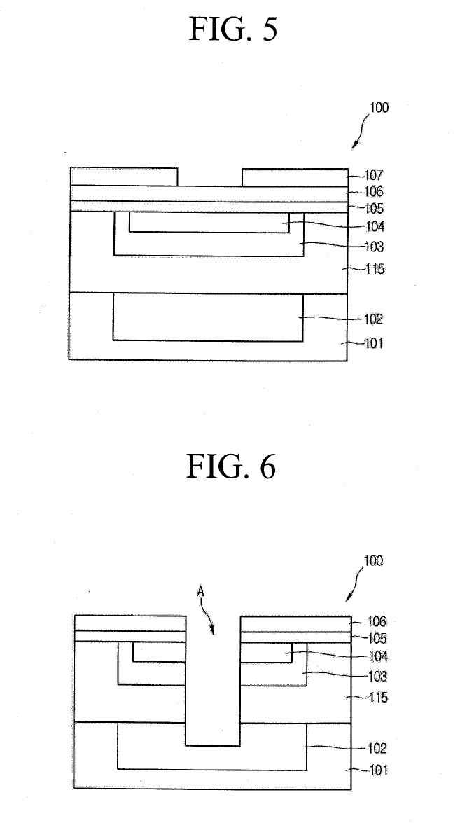

Example FIGS. 5 to 8 illustrate processes for forming the trench and oxide layer 108 in accordance with embodiments.

As illustrated in example FIG. 5, oxide layer 105 and nitride layer 106 can be sequentially formed on and/or over the entire surface of epitaxial layer 115. Photoresist 107 can then be coated on and/or over nitride layer 106. Photoresist 107 can then be selectively patterned through an exposure and development process, thereby defining the trench region.

As illustrated in example FIG. 6, nitride layer 106 and oxide layer 105 can be selectively removed by using patterned photoresist 107 as a mask. Subsequently, collector region 102 and epitaxial layer 115 including emitter region 104 and base region 103 are selectively removed to expose a portion of the surface of collector region 102, thereby forming trench A extending through nitride layer 106, oxide layer 105, emitter region 104 and base region 103. After formation of trench A, photoresist 107 is removed.

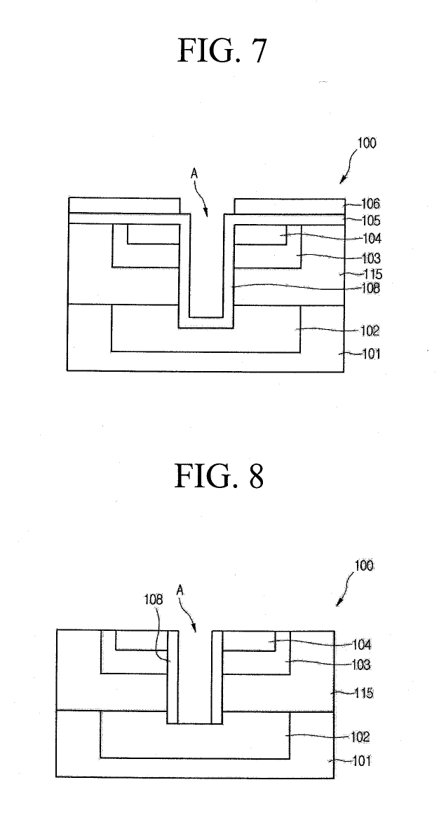

As illustrated in example FIG. 7, oxide layer 108 can then be formed in trench A through a thermal oxidation process in which an oxygen reaction is induced at high temperature. Nitride layer 106 can then be removed after formation of oxide layer 108. Nitride layer 106 prevents thickening of oxide layer 105 on and/or over epitaxial layer 115 during formation of oxide layer 108 in trench A.

Oxide layer 108 can serve to electrically isolate epitaxial layer 115 including emitter region 104 and base region 103 from polysilicon layer 110, which will be formed later. In essence, a portion of oxide layer 108 positioned at a bottom surface of trench A can be removed in order to permit contact between polysilicon layer 110 and collector region 102. Oxide layer 105 formed on and/or over epitaxial layer 115 can be removed at the same speed and the same depth. Accordingly, a lower layer of bipolar transistor 100 can be protected through the above process.

As illustrated in example FIG. 8, after removal of nitride layer 106, portions of oxide layers 105, 108 can be removed. For example, an anisotropic etching process can be performed such that oxide layer 105 on and/or over epitaxial layer 115 and oxide layer 108 provided at the bottom surface of trench A are removed, leaving oxide layer 108 on sidewalls of trench A.

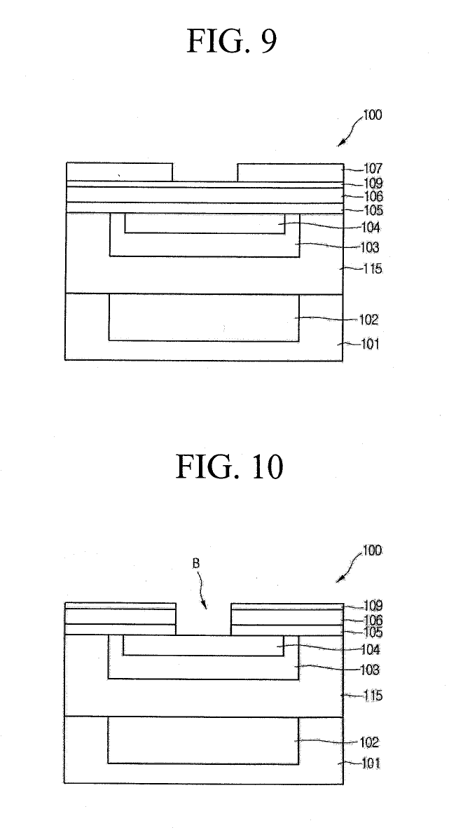

As illustrated in example FIG. 9, in accordance with another embodiment, an ONO mask layer including first oxide layer 105, nitride layer 106 and second oxide layer 109 can be sequentially formed on and/or over the entire surface of epitaxial layer 115. Photoresist 107 can then be coated on and/or over second oxide layer 109. Thereafter, photoresist 107 can be selectively patterned through an exposure and development process, thereby defining a trench region.

As illustrated in example FIG. 10, first oxide layer 105, nitride layer 106, and second oxide layer 109 can then be selectively removed using patterned photoresist 107 as a mask, thereby forming first trench B. Photoresist can then be removed after formation of first trench B.

As illustrated in example FIG. 11 epitaxial layer 115 including emitter region 104 and base region 103 and collector region 102 can then be selectively removed using first oxide layer 105, nitride layer 106 and second oxide layer 109 as mask layers to form second trench A exposing a portion of the surface of collector region 102. Accordingly, ONO mask layer including first oxide layer 105, nitride layer 106 and second oxide layer 109 permits various etching processes to be performed using the ONO mask.

Oxide layer 108 can then be formed in second trench A, and portions of second oxide layer 109 and nitride layer 106 can be removed, so that first oxide layer 105 remains. First oxide layer 105 corresponds to oxide layer 15 in accordance with the first embodiment. Accordingly, since first oxide layer 105 has the same structure and functions the same as that of the first embodiment, details thereof will be omitted in order to avoid redundancy.

Thereafter, first oxide layer 105 and a portion of oxide layer 108 in second trench A can be removed. For example, an anisotropic etching process can be performed so that first oxide layer 105 and oxide layer 108 provided on the bottom surface of second trench A are removed, leaving only oxide layer 108 provided on the sidewalls of second trench A. Accordingly, the structure of bipolar transistor 100 as illustrated in example FIG. 8 is complete.

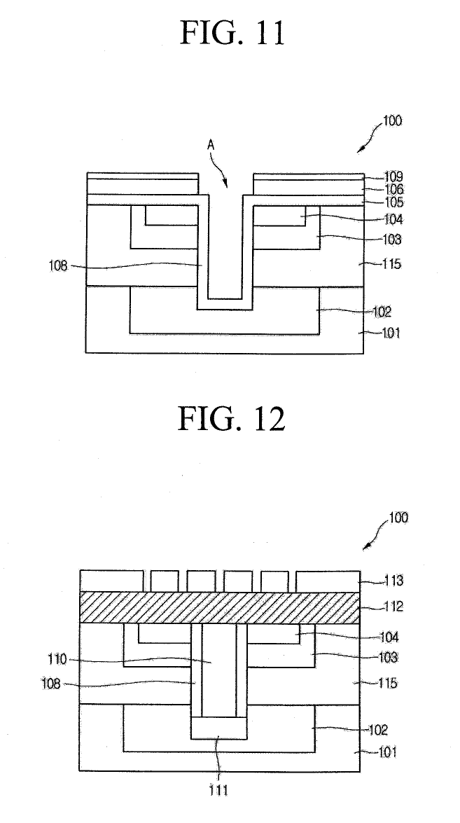

As illustrated in example FIG. 12, after formation of trench A having oxide layer 108 provided on sidewalls thereof, polysilicon can be injected into trench A, thereby forming polysilicon layer 110. When the polysilicon is doped with high-density N type impurity ions, the N type impurity ions may penetrate into a portion of collector region 102 when polysilicon layer 110 is formed in trench A, so that diffusion region (sink) 111 can be formed simultaneously with polysilicon layer 110. The polysilicon may be coated on a portion of the top surface of epitaxial layer 115 including emitter region 104 and base region 103, as well as inside trench A. In this case, the process of removing the polysilicon on the top surface of epitaxial layer 115 may be additionally performed through an anisotropic etching process or a chemical mechanical polishing (CMP) process. Epitaxial layer 115 can then be cleaned to remove impurities generated during the above process, and interlayer dielectric layer 112 can be formed on and/or over the surface of base region 103, emitter region 104, epitaxial layer 115, and polysilicon layer 110.

After formation of interlayer dielectric layer 112, photoresist 113 can then be coated on the interlayer dielectric layer 112, and then selectively patterned through an exposure and development process, thereby defining an electrode region. Interlayer dielectric layer 112 can be selectively removed using photoresist 113 as a mask layer to form a plurality of contacts holes exposing base region 103, emitter region 104, and polysilicon layer 110. Photoresist 113 can then be removed. Metal layer 114 can then be formed on and/or over interlayer dielectric layer 112. Metal layer 114 can then be selectively removed through a photolithography process

As illustrated in example FIG. 3, metal layer 114 can be formed as base electrode 114a, emitter electrode 114b and collector electrode 114c which through the contact holes are electrically connected to base region 103, emitter region 104, and polysilicon layer 110, respectively.

Because polysilicon layer 110 connected to collector region 102 passes through base region 103 and emitter region 104, a plurality of base electrodes 114a and emitter electrodes 114b may be formed around polysilicon layer 110. Accordingly, as illustrated through a hatched line in example FIG. 3, it is possible to minimize the path of current flowing to/from emitter region 104 to collector electrode 114c through collector region 102 and polysilicon layer 110, and a plurality of emitter electrodes and base electrodes can be effectively arranged.

Moreover, the size of a collector can be reduced due to an electrode structure and a collector region that is formed through an emitter region and a base region, and the performance of a transistor can be improved by minimizing the resistance of the collector.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A bipolar transistor comprising:
a collector region formed in a substrate;
an epitaxial layer formed over the substrate including the collector region;
a base region formed in the epitaxial layer;
an emitter region formed in the base region;
an oxide layer formed on sidewalls of a trench extending through the emitter region, the base region, the epitaxial layer and in the collector region; and
a polysilicon layer formed in the trench.

2. The bipolar transistor as claimed in claim 1, further comprising a diffusion region formed in a lower portion of the collector region and contacting the trench.

3. The bipolar transistor as claimed in claim 1, further comprising:
an interlayer dielectric layer formed over the epitaxial layer, said interlayer dielectric layer having a plurality of contact holes exposing the base region, the emitter region, and the polysilicon layer; and
an electrode formed in each one of the plurality of contact holes in electrical communication with the base region, the emitter region, and the polysilicon layer, respectively.

4. The bipolar transistor as claimed in claim 3, wherein the plurality of contact holes and corresponding electrode are formed over at least one of the base region and the emitter region.

5. The bipolar transistor as claimed in claim 1, wherein at least one of the polysilicon layer and the diffusion region is doped with N type impurities.

6. The bipolar transistor as claimed in claim 1, wherein the collector region comprises an N+ type buried layer, the base region comprises a P+ type base region and the emitter region comprises an N+ type emitter region.

7. A method for manufacturing a bipolar transistor, the method comprising:
forming a collector region in a substrate;
forming an epitaxial layer over the substrate including the collector region;
forming a base region in the epitaxial region;
forming an emitter region in the base region;
forming a trench through the emitter region, the base region, the epitaxial layer and in the collector region;
forming an oxide layer on sidewalls of the trench; and then
forming a polysilicon layer in the trench.

8. The method as claimed in claim 7, wherein forming the polysilicon layer comprises forming a diffusion region in the collector region and in contact with the polysilicon layer.

9. The method as claimed in claim 7, wherein forming the oxide layer comprises:
sequentially forming a second oxide layer and a nitride layer over the epitaxial layer;
forming the trench;
forming the oxide layer on sidewalls of the trench;
removing the nitride layer; and then
removing the second oxide layer and a portion of the first oxide layer provided at a bottom surface of the trench.

10. The method as claimed in claim 9, wherein sequentially forming the oxide layer and the nitride layer further comprises:
coating a photoresist over the nitride layer;
exposing the nitride layer by selectively patterning the photoresist; and then
selectively removing portions of the nitride layer and the second oxide layer using the patterned photoresist as a mask;
forming the trench exposing a portion of the surface of the collector region by selectively removing portions of the collector region, the epitaxial layer, the emitter region and the base region; and then
removing the photoresist.

11. The method as claimed in claim 7, wherein forming the oxide layer comprises:
sequentially forming a second oxide layer, a nitride layer, and a third oxide layer over the epitaxial layer;
forming a second trench exposing the emitter region by removing portions of the second oxide layer, the nitride layer, and the third oxide layer;
forming the trench by performing an etching process using the third oxide layer as an etching mask;
forming the oxide layer on sidewalls of the trench;
removing the third oxide layer and the nitride layer; and then
removing the second oxide layer and a portion of the oxide layer provided over a bottom surface of the trench.

12. The method as claimed in claim 11, wherein sequentially forming the second oxide layer, the nitride layer, and the third oxide layer comprises:
coating a photoresist over the third oxide layer;
patterning the photoresist;
forming the first trench exposing a portion of the surface of the collector region by selectively removing portions of the collector region, the epitaxial layer, the emitter region and the base region; and then
removing the photoresist.

13. The method as claimed in claim 8, wherein forming the diffusion region comprises doping the polysilicon layer.

14. The method as claimed in claim 13, wherein the polysilicon layer is doped with high-density N type impurity ions.

15. The method as claimed in claim 7, further comprising:
forming an interlayer dielectric layer over the epitaxial layer;
forming a plurality of contact holes in the interlayer dielectric layer exposing the base region, the emitter region and the polysilicon layer; and then
forming an electrode in each one of the plurality of contact holes in electrical communication with the base region, the emitter region and the polysilicon region, respectively.

16. The method as claimed in claim 7, wherein forming the polysilicon layer comprises:
forming the polysilicon layer in the trench and over the substrate including the emitter region, the base region and the epitaxial layer; and then
removing a portion of the polysilicon layer provided over the emitter region, the base region, and the epitaxial layer.

17. The method as claimed in claim 15, wherein forming an electrode, a plurality of contact holes and electrodes are formed on at least one of the base region and the emitter region.

18. The method as claimed in claim 7, wherein the collector region comprises an N+ type buried layer, the base region is formed by implanting P type impurity ions, and the emitter region is formed by implanting N type impurity ions.

19. An apparatus comprising:
a first region composed of N+ type impurity ions formed in a substrate;
an epitaxial layer formed over the substrate including the first region;
a second region composed of P+ type impurity ions formed in the epitaxial layer;
a third region composed of N+ type impurity ions formed in the second region;
an oxide layer formed on sidewalls of a trench extending through the third region, the second region, the epitaxial layer and in the first region;
a polysilicon layer formed in the trench extending through the third region, the second region and the epitaxial layer and into the first region;
a fourth region composed of N type impurity ions formed in the first region under the oxide layer and the polysilicon layer; and
a plurality of electrodes formed in electrical communication with the second region, the third region, and the polysilicon layer, respectively.

20. The apparatus of claim 19, further comprising:
an interlayer dielectric layer formed over the epitaxial layer, the third region, the second region, the polysilicon layer and the oxide layer;
a plurality of contact holes formed in the interlayer dielectric layer exposing the second region, the third region and the polysilicon layer,
wherein the plurality of electrodes are formed in each one of the plurality of contact holes.
